(19) United States
(12) Patent Application Publication
(10) Pub. No.: US 2009/0050915 A1
(43) Pub. Date: Feb. 26, 2009

(54) Group III-V nitride semiconductor substrate and method for producing same

(75) Inventor: Shunsuke Yamamoto, Hitachi (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: HITACHI CABLE, LTD., Tokyo (JP)

(21) Appl. No.: 12/213,391

(22) Filed: Jun. 18, 2008

(30) Foreign Application Priority Data
Aug. 22, 2007 (JP) 2007-216223

(51) Int. Cl. H01L 33/00; H01L 21/00

(52) U.S. Cl. 257/94; 438/47; 257/E33.001; 257/E21.001

(57) ABSTRACT

A group III-V nitride semiconductor substrate includes a first region of group III-V nitride semiconductor crystal grown on a facet on a heterosubstrate, and a second region of the group III-V nitride semiconductor crystal grown on a plane with a predetermined plane orientation on the heterosubstrate. The first region has an area ratio of not more than 10% to the second region in a plane of the substrate. A method for producing a group III-V nitride semiconductor substrate includes a first crystal growth step of supplying a source gas of a group III-V nitride semiconductor onto a heterosubstrate at a first partial pressure to grow the group III-V nitride semiconductor on a plane with a predetermined plane orientation and a facet on the heterosubstrate, and a second crystal growth step of supplying onto the heterosubstrate the source gas at a second partial pressure higher than the first partial pressure to grow the semiconductor on the plane with the predetermined plane orientation and the facet after the first crystal growth step is conduced for a predetermined time period so as to suppress a crystal growth of the semiconductor on the facet.

The present application is based on Japanese patent application No. 2007-216223 filed on Aug. 22, 2007, the entire contents of which are incorporated herein by reference.

### BACKGROUND OF THE INVENTION

1. Field of the Invention

The invention relates to a group III-V nitride semiconductor substrate, and a method for producing the group III-V nitride semiconductor substrate. Particularly, the invention relates to the group III-V nitride semiconductor substrate with a reduced rate in crack occurrence, and a method for producing the group III-V nitride semiconductor substrate.

2. Description of the Related Art

A group III-V nitride semiconductor layer of gallium nitride (GaN), indium gallium nitride (InGaN), and gallium aluminum nitride (GaAlN) is epitaxially grown on a growth substrate by metal organic chemical vapor deposition (MOVPE), molecular beam epitaxy (MBE), hydride vapor phase epitaxy (HVPE) or the like.

Since there is no growth substrate to match in lattice constant to the group III-V nitride semiconductor layer, it is difficult to grow a low-defect group III-V nitride semiconductor layer, so that the group III-V nitride semiconductor layer formed during the growth must have many crystal defects such as a dislocation. The crystal defect is a factor to prevent improvement in device characteristics of a light-emitting device etc. formed by using the group III-V nitride semiconductor layer. Thus, it is desired to form a low-defect group III-V nitride semiconductor.

As a method for producing a substrate of low-defect group III-V nitride semiconductor used for fabricating a high-performance light-emitting device and the like, ELO (epitaxial lateral overgrowth) is developed where a mask with an opening is formed on a substrate to grow a GaN layer with dislocation reduced by growing laterally the GaN layer through the opening (e.g., see JP-A-11-251253).

Furthermore, FIELO (facet-initiated epitaxial lateral overgrowth) is developed where penetrating dislocation reaching the top surface of an epitaxial growth layer is reduced such that a silicon oxide mask with an opening is formed on a substrate and facets are formed at the opening so as to change the propagation direction of dislocations (e.g., see A. Usui, et. al., Jpn. J. Appln. Phys. Vol. 36 (1997) L899).

Also, DEEP (dislocation elimination by the epi-growth with inverted-pyramidal pits) is developed where GaN is grown by using a mask of silicon nitride etc. patterned on a gallium arsenide (GaAs) substrate, and pits surrounded by facets are intentionally formed on the crystal surface so as to collect dislocations at the bottom of the pits whereby the other region than the pits can be reduced in dislocation density (e.g., see JP-A-2003-165799).

The above ELO, FIELO, and DEEP use the function that dislocations propagating in crystal during the crystal growth are bent in its propagation direction by the facets, whereby the dislocation can be prevented from reaching the top surfaces of the crystal so as to reduce a dislocation density on the surface of the substrate. Furthermore, by growing the crystal while forming pits surrounded by facets at the interface of crystal growth so as to collect densely dislocations at the bottom of the pits, it is possible to eliminate the dislocations by colliding with each other at the bottom of the pits, or to prevent the dislocations from reaching the top surface by forming a dislocation loop.

As described in JP-A-H11-251253, JP-A-2003-165799, and A. Usui, et. al., Jpn. J. Appln. Phys. Vol. 36 (1997) L899, all the methods for growing a crystal of group III-V nitride semiconductor are conducted such that the facet formation can change the propagation direction of crystal dislocations so as to have a low-dislocation density crystal surface. After the crystal is thus epitaxially grown, the surface of the crystal is lapped such that irregularity left on the crystal surface due to the facet formation are removed to have a flat surface of the crystal.

However, the above methods for growing a crystal of group III-V nitride semiconductor described in JP-A-H11-251253, JP-A-2003-165799, and A. Usui, et. al., Jpn. J. Appln. Phys. Vol. 36 (1997) L899 have the problem that crack occurs during the surface lapping of the grown substrate. In this respect, the inventor has found that the rate of crack occurrence depends on the ratio of a facet growth region to a crystal surface area.

### SUMMARY OF THE INVENTION

Accordingly, an object of the invention is to provide a III-V nitride semiconductor substrate that is significantly reduced in rate of crack occurrence during the surface lapping of a grown substrate, and a method for manufacturing the III-V nitride semiconductor substrate.

(1) According to one embodiment of the invention, a group III-V nitride semiconductor substrate comprises:

a first region of group III-V nitride semiconductor crystal grown on a facet on a heterosubstrate; and

a second region of the group III-V nitride semiconductor crystal grown on a plane with a predetermined plane orientation on the heterosubstrate,

wherein the first region comprises an area ratio of not more than 10% to the second region in a plane of the substrate.

In the above embodiment (1), the following modifications and changes can be made.
(i) The heterosubstrate comprises a sapphire substrate, and the sapphire substrate is removed.
(ii) The plane with the predetermined plane orientation comprises a (0001) plane.

(2) According to another embodiment of the invention, a method for producing a group III-V nitride semiconductor substrate comprises:

a first crystal growth step of supplying a source gas of a group III-V nitride semiconductor onto a heterosubstrate at a first partial pressure to grow the group III-V nitride semiconductor on a plane with a predetermined plane orientation and a facet on the heterosubstrate; and

a second crystal growth step of supplying onto the heterosubstrate the source gas of the group III-V nitride semiconductor at a second partial pressure higher than the first partial pressure to grow the group III-V nitride semiconductor on the plane with the predetermined plane orientation and the facet on the heterosubstrate after the first crystal growth step is conduced for a predetermined time period so as to suppress a crystal growth of the semiconductor on the facet.

In the above embodiment (2), the following modifications and changes can be made.
(iii) The second crystal growth step comprising supplying the source gas at the second partial pressure such that a region where the semiconductor is grown on the facet comprises an area ratio of not more than 10% to a region where the semiconductor is grown on the plane with the predetermined plane orientation.
(iv) The plane with the predetermined plane orientation comprises a (0001) plane.

### BRIEF DESCRIPTION OF THE DRAWINGS

The invention will be explained in more detail in conjunction with appended drawings, wherein:

FIGS. 1A to 1F are schematic cross sectional views showing a method of making a group III-V nitride semiconductor substrate according to a preferred embodiment of the invention;

FIG. 2 is a schematic cross sectional view showing a test method for a group III-V nitride semiconductor substrate of the preferred embodiment; and

FIG. 3 is a graph showing a rate of crack occurrence when the ratio of a total area of c-plane growth region to that of facet-plane growth region is changed, where the surface of a substrate is lapped.

### DESCRIPTION OF THE PREFERRED EMBODIMENTS

A preferred embodiment of the present invention will be described hereinafter by referring to the accompanying drawings.

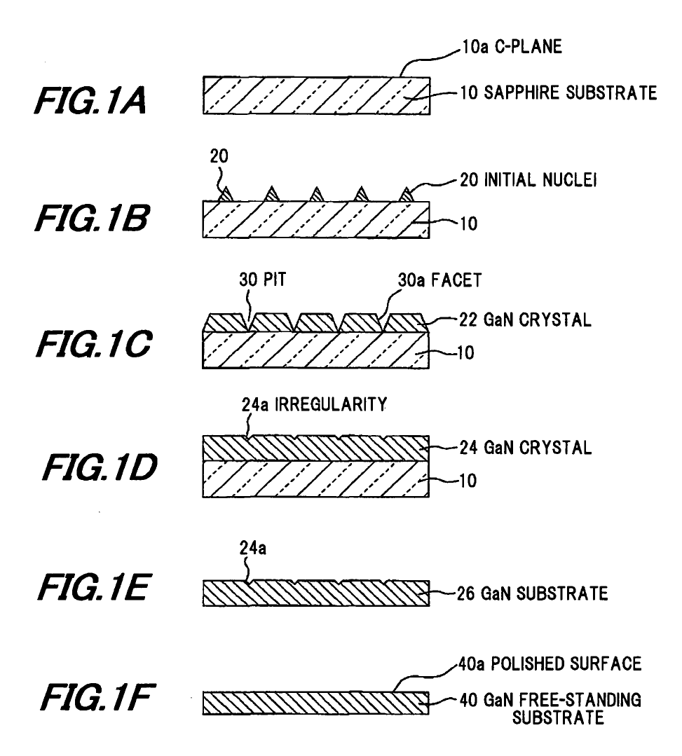

FIGS. 1A to 1F show an example of a process flow in making a group III-V nitride semiconductor substrate in the preferred embodiment according to the invention.

In this embodiment, first, GaN crystal as a group III-V nitride semiconductor crystal is epitaxially grown by a predetermined thickness on a sapphire substrate 10 as a heterosubstrate by HVPE (hydride vapor phase epitaxy) where gallium chloride (GaCl) gas, and ammonia (NH₃) gas are used as a source material. Then, the sapphire substrate 10 is removed from the GaN crystal grown on the sapphire substrate 10 to obtain the GaN substrate (GaN free-standing substrate) as a group III-V nitride semiconductor substrate.

In detail, at first, the sapphire substrate 10 having (0001) plane, i.e. c-plane 10a, as a predetermined crystal orientation as shown in FIG. 1A is placed in an HVPE reactor. In the HVPE reactor, GaCl and NH₃ at a first partial pressure are used as a source gas for GaN crystal growth. As a carrier gas, a mixed gas of 5% of hydrogen (H₂) and 95% of nitrogen (N₂) is used. Growth conditions of the GaN crystals are normal pressure and 1050° C. as a temperature of the sapphire substrate 10.

When the crystal growth is started, plural three-dimensional island-shaped initial nuclei 20 composed of GaN crystal are produced on the sapphire substrate 10 as shown in FIG. 1B. Then, facets 30a are produced on side wall of the initial nuclei 20 to progress the growth of GaN crystals as shown in FIG. 1C. Along with the progress of the growth of the GaN crystal, top regions of the GaN crystals 22 become flattened. As a consequence, the flattened GaN crystal 22 grows in horizontal direction to the surface of the sapphire substrate 10.

The crystal is grown by a predetermined time period while allowing the exposure of the facet 30a to exhibit the irregularities at the growth initial stage of the GaN crystal. Then, the growth condition of the GaN crystal is changed to a predetermined crystal growth condition. For example, after the predetermined time period elapsed since the beginning of crystal growth, the first partial pressure of GaCl is changed to a second partial pressure that is by a predetermined value higher than the first partial pressure at beginning of crystal growth, whereby the crystal growth on the facet 30a is suppressed. More specifically, the GaCl partial pressure is changed such that, in the entire surface of crystal growth, a total area of first region where GaN crystal grows on facet becomes 10% or less to a total area of second region where GaN crystal grows on c-plane.

When the crystal growth proceeds, the growth interface between the GaN crystal 22 and a vapor phase of the source gas used for the GaN crystal 22 is not completely flattened, but plural pits 30 surrounded by the facets 30a are generated on the surface of the GaN crystal 22. Subsequently, when the GaN crystal is grown, as shown in FIG. 1D, the surface of the GaN crystal 24 is further flattened. In this state, the surface of the GaN crystal 24 is not completely flattened and has plural irregularities 24a thereon.

Then, the sapphire substrate 10 with GaN crystal 24 formed thereon is taken out of the HVPE reactor, and the sapphire substrate 10 is separated therefrom. For example, a high-power ultraviolet laser beam with a wavelength for transmitting the sapphire substrate 10 and being absorbed by the GaN crystal 24 is irradiated from the opposite side to a side of the sapphire substrate 10 where the GaN crystal 24 is formed. Thus, by fusing the interface region between the GaN crystal 24 and the sapphire substrate 10, the sapphire substrate 10 is separated from the GaN crystal 24 (laser lift-off method). Thus, a GaN substrate 26 is obtained as shown in FIG. 1E.

Then, by lapping a Ga surface as a surface of the GaN substrate 26, as shown in FIG. 1F, a GaN free-standing substrate 40 with a polished surface 40a is obtained. The GaN substrate 26 is lapped by using diamond particles having a predetermined grain size. As an example, diamond particles having # 500 grain size are used.

Meanwhile, at the step in FIG. 1B, by increasing the GaCl partial pressure by a predetermined value after a predetermined time period elapsed since the beginning of crystal growth, the initial nuclei 20 on the sapphire substrate 10 can be also reduced in density which are causing the irregularities with the facet planes exposed at the initial stage of crystal growth. As a consequence, a region where the irregularities 24a are left on the surface of the GaN crystal 24 can be reduced at the termination of crystal growth as shown in FIG. 1D.

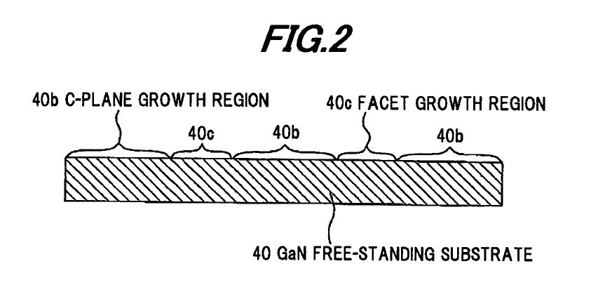

FIG. 2 shows a conceptual measurement test for the group III-V nitride semiconductor substrate of the embodiment.

The surface of the GaN free-standing substrate 40 as the group III-V nitride semiconductor substrate obtained by the above production method of the group III-V nitride semiconductor substrate in FIGS. 1A to 1F is measured by using a fluorescence microscope. The measurement test is conducted for cracks generated in the GaN free-standing substrate 40 during the surface lapping, and, during the crystal growth, area of region where GaN crystal grows on c-plane (c-plane growth region 40b), and area of region where GaN crystal grows on facet (facet growth region 40c).

Table 1 shows the rate of a total area of facet growth region relative to a total area of c-plane growth region where GaN crystal is grown on a sapphire substrate at various GaCl partial pressures.

TABLE 1

| | Rate of total area of facet growth |
|---|---|
| GaCl Partial Pressure | region to that of c-plane |
| (Pa) | growth region (%) |
| 0.51 × 10² | 95 |
| 1.01 × 10² | 84 |
| 2.03 × 10² | 73 |
| 3.04 × 10² | 62 |
| 4.05 × 10² | 51 |

In Table 1, a NH₃ partial pressure in a source gas is set 5.07×10² Pa, while a GaCl partial pressure in the source gas is changed; and a GaN substrate is formed. Namely, a GaCl partial pressure in the source gas is set 0.51×10² Pa, 1.01×10² Pa, 2.03×10² Pa, 3.04×10² Pa, or 4.05×10² Pa and GaN substrates are formed. The other growth conditions are the same as described above referring to FIGS. 1A to 1F. The GaN crystals grown have a total thickness of 600 μm.

The GaN crystal 24 grown on the sapphire substrate 10 by using the various GaCl partial pressures is separated from the sapphire substrate 10 by using the laser lift-off method. Then, a surface (i.e., Ga surface) of the GaN crystal 24 is lapped by using diamond particles having a predetermined grain size to obtain the GaN free-standing substrate 40 having a thickness of 400 μm. The lapping is conducted such that a grinding stone with fixed abrasive grains is used which has 200 mm in diameter and diamond particles with # 500 in grain size embedded therein, the grinding stone is rotated at 1500 rpm, and the grinding stone is set 0.1 μm/second in forward speed. Then, fluorescence microscope is used to measure the area of a region where GaN crystal grows at c-plane (c-plane growth), and the area of a region where GaN crystal grows on facet (facet growth) in the surface of the GaN free-standing substrate 40.

As seen from Table 1, it is confirmed that the rate of the total area of facet growth region to that of c-plane growth region decreases substantially linearly along with an increase in GaCl partial pressure from 0.51×10² Pa through 1.01×10² Pa, 2.03×10² Pa and 3.04×10² Pa up to 4.05×10² Pa.

Table 2 shows a rate of the total area of facet growth region to that of c-plane growth region when GaN crystals are grown on a sapphire substrate at various GaCl partial pressures by the growth method of the III-V nitride semiconductor crystal in the embodiment of the invention.

TABLE 2

| GaCl partial pressure at | Rate of total area of facet |
|---|---|
| initial stage of crysta | growth region to that of |
| l growth stage (Pa) | c-plane growth region (%) |
| 0.51 × 10² | 40 |
| 1.01 × 10² | 29 |
| 2.03 × 10² | 18 |
| 3.04 × 10² | 9 |
| 4.05 × 10² | 5 |

In this embodiment, the growth condition of GaN crystals is changed halfway in the crystal growth, and GaN crystals are grown. Specifically, the respective GaCl partial pressures are increased to 1.52×10³ Pa after 10 minutes elapses since the beginning of crystal growth at the GaCl partial pressures as shown in Table 1. The other crystal growth condition, lift-off method, polishing condition, and test method are the same as in Table 1.

In Table 2, the rate of the total area of facet growth region to the total area of c-plane growth region decreases as compare to that in Table 1 by increasing the GaCl pressure after a predetermined time period elapses since the beginning of crystal growth. Particularly, it is confirmed that the rate of the total area of facet growth region to the total area of c-plane growth region becomes 10% or less in the case that the GaCl partial pressure is 3.04×10² Pa or 4.05×10² Pa, and the GaCl partial pressure is increased to 1.52×10³ Pa after 10 minutes elapses since the beginning of crystal growth.

Table 3 shows test results when the rate of crack occurrence is measured by changing the rate of the total area of facet growth region to that of c-plane growth region, where the surface of a substrate is lapped.

TABLE 3

| Rate of total area of facet | | | |
|---|---|---|---|
| growth region to that of | Number of | | Rate of crack |
| c-plane growth region | tested | Number of wafers | occurrence |
| (%) | wafers | with crack occurred | (%) |
| 90 to 100 | 50 | 29 | 58 |
| 80 to 90 | 50 | 28 | 56 |
| 70 to 80 | 50 | 30 | 60 |
| 60 to 70 | 50 | 32 | 64 |
| 50 to 60 | 50 | 28 | 56 |
| 40 to 50 | 50 | 23 | 46 |
| 30 to 40 | 50 | 18 | 36 |
| 20 to 30 | 50 | 16 | 32 |
| 10 to 20 | 50 | 13 | 26 |
| 0 to 10 | 50 | 2 | 4 |

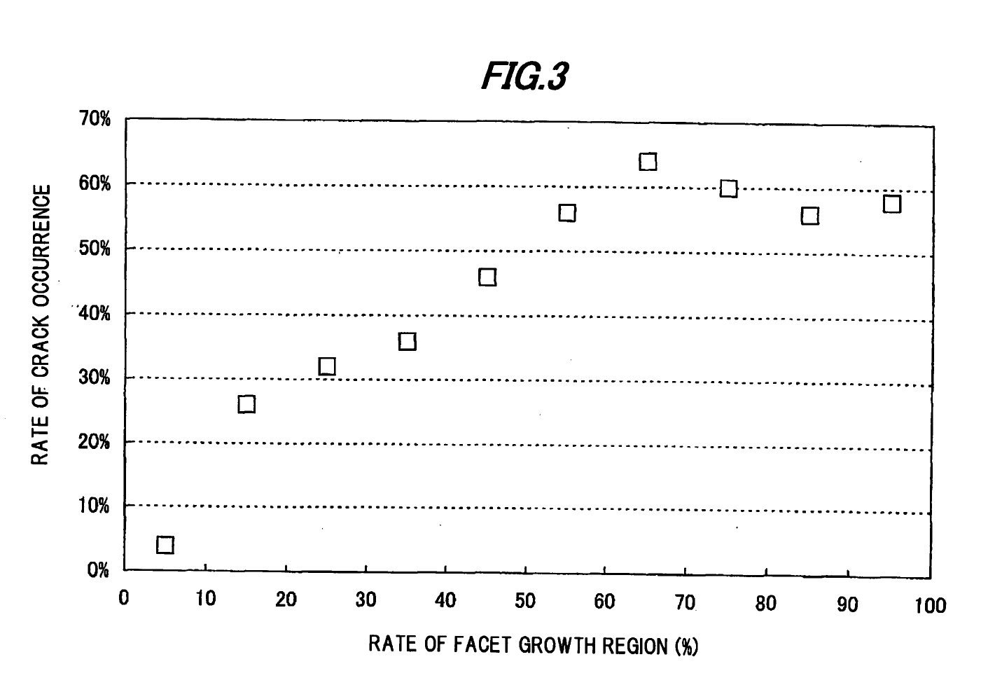

FIG. 3 is a graph showing the rate of crack occurrence when changing the rate of the total area of facet growth region to that of c-plane growth region, where the surface of a substrate is lapped.

First, plural GaN substrates are formed by changing the crystal growth conditions as indicated in Tables 1 and 2. Fifty GaN substrates are each prepared when a rate of the total area of facet growth region to that of c-plane growth region is changed such as 90% to 100%, 80% to 90%, 70% to 80%, 60% to 70%, 50% to 60%, 40% to 50%, 30% to 40%, 20% to 30%, 10% to 20%, and 0% to 10%. Then, the surface (Ga surface) of each GaN substrate is lapped with diamond particles (# 500 grain size), whereby the occurrence rate of cracks is measured in each substrate.

Referring to Table 3 and FIG. 3, the rate of crack occurrence is 4% for the GaN substrates formed in the range of 0% to 10% percents in the rate of the total area of facet growth region to that of c-plane growth region.

The reasons why the rate of crack occurrence when lapping the GaN substrate is differentiated due to difference in the rate of the total area of facet growth region to that of c-plane growth region are estimated by the inventor as follows.

Namely, the inventor estimates that the region where GaN crystal grows on c-plane is different in chemical and physical properties thereof from the region where GaN crystal grows on facet, so that the lapping causes a processing strain occurred nonuniformly in the region where GaN crystal grows on c-plane and the region where GaN crystal grows on facet, and the processing strain causes a stress occurred on the surface of the GaN substrate, whereby crack can be easily occurred. Also, the inventor estimates that the irregularities due to the facet structure are left on the surface of the GaN substrate, thereby the shape of the surface of the GaN substrate becomes nonuniform, and as a result, the lapping of the substrate can easily cause the crack.

These estimations are made based on the following inventor's knowledge. Namely, it is known that, during crystal growth, the region where GaN crystal grows on facet is doped with oxygen more than the region where GaN crystal grows on c-pane. When the inventor analyzes the surface of the GaN substrate by SIMS (secondary ion mass spectroscopy), it is found that the concentration of silicon (Si), which is contained in silica used as a material of a reaction tube for the crystal growth, is different between the region where GaN crystal grows on facet and the region where GaN crystal grows on c-plane. By the inventor, it is found that the Si concentration in the region where GaN crystal grows on facet is 6×10¹⁸ cm⁻³, while the Si concentration in the region where GaN crystal grows on c-plane is 1×10¹⁷ cm⁻³.

Thus, the inventor has found that the chemical and physical properties are different between the region where GaN crystal grows on c-plane and the region where GaN crystal grows on facet. The irregularities left on the crystal surface due to the region where GaN crystal grows on facet are necessary to eliminate by polishing. The polishing is conducted by three steps of lapping, precision polishing, and chemical-mechanical polishing (CMP). In that occasion, the particle diameter of abrasive grains is made to be smaller in the order of the lapping, precision polishing, and chemical-mechanical polishing, whereby the wafer surface can be mirror finished. In the lapping that the particle diameter of the abrasive grains used for lapping is larger than that used for the other ways, the substrate is most hard damaged. Particularly, the inventor estimates that cracks may occur easily on the substrate when lapping the substrate since the region where GaN crystal grows on c-plane and the region where GaN crystal grows on facet are mixed which are different each other in the chemical and mechanical properties.

As described above, it is confirmed that the rate of the total area of facet growth region to that of c-plane growth region needs only to be at 10% or less in order to reduce remarkably the rate of crack occurrence when a GaN substrate grown on the sapphire substrate 10 is separated therefrom and then lapped.

### Advantages of the Embodiment

According to the preferred embodiment of the invention, when a predetermined partial pressure of a source gas is increased after a predetermined time period elapses since the beginning of crystal growth of GaN crystal as a III-V nitride semiconductor crystal, the rate of the total area of facet growth region to that of c-plane growth region can be adjusted at 10% or less. As a result, the rate of crack occurrence can be significantly reduced during the surface lapping of the grown group III-V nitride semiconductor substrate

Although the invention has been described hereinabove in accordance with the preferred embodiments, the invention claimed in the appended claims is not restricted by the above-described embodiments. Furthermore, it is to be noted that all the combinations of the characteristic features described in the embodiments are not necessarily required for the means of solving the problems to be solved by the invention.

What is claimed is:

1. A group III-V nitride semiconductor substrate, comprising:
a first region of group III-V nitride semiconductor crystal grown on a facet on a heterosubstrate; and
a second region of the group III-V nitride semiconductor crystal grown on a plane with a predetermined plane orientation on the heterosubstrate,
wherein the first region comprises an area ratio of not more than 10% to the second region in a plane of the substrate.

2. The group III-V nitride semiconductor substrate according to claim 1, wherein:
the heterosubstrate comprises a sapphire substrate, and
the sapphire substrate is removed.

3. The III-V nitride semiconductor substrate according to claim 1, wherein:
the plane with the predetermined plane orientation comprises a (0001) plane.

4. A method for producing a group III-V nitride semiconductor substrate, comprising:
a first crystal growth step of supplying a source gas of a group III-V nitride semiconductor onto a heterosubstrate at a first partial pressure to grow the group III-V nitride semiconductor on a plane with a predetermined plane orientation and a facet on the heterosubstrate; and
a second crystal growth step of supplying onto the heterosubstrate the source gas of the group III-V nitride semiconductor at a second partial pressure higher than the first partial pressure to grow the group III-V nitride semiconductor on the plane with the predetermined plane orientation and the facet on the heterosubstrate after the first crystal growth step is conduced for a predetermined time period so as to suppress a crystal growth of the semiconductor on the facet.

5. The method according to claim 4, wherein:
the second crystal growth step comprising supplying the source gas at the second partial pressure such that a region where the semiconductor is grown on the facet comprises an area ratio of not more than 10% to a region where the semiconductor is grown on the plane with the predetermined plane orientation.

6. The method according to claim 4, wherein:
the plane with the predetermined plane orientation comprises a (0001) plane.
